(19) United States
(12) Patent Application Publication
(10) Pub. No.: US 2012/0252209 A1
(43) Pub. Date: Oct. 4, 2012

(54) PLASMA NITRIDING METHOD, PLASMA NITRIDING APPARATUS AND METHOD OF MANUFACTURING SEMICONDUCTOR DEVICE

(75) Inventors: Yoshiro Kabe, Nirasaki City (JP); Yoshihiro Sato, Nirasaki City (JP)

(73) Assignee: TOKYO ELECTRON LIMITED, Tokyo (JP)

(21) Appl. No.: 13/433,746

(22) Filed: Mar. 29, 2012

(30) Foreign Application Priority Data
Mar. 31, 2011 (JP) 2011-080077

(51) Int. Cl. H01L 21/768; C23C 14/06; H01L 21/318

(52) U.S. Cl. 438/653; 438/792; 118/50.1; 257/E21.293; 257/E21.584

(57) ABSTRACT

A plasma nitriding method includes placing, in a processing chamber, a target object having a structure including a first portion containing a metal and a second portion containing silicon to expose surfaces of the first and the second portion; and performing a plasma process on the target object to selectively nitride the surface of the first portion such that a metal nitride film is selectively formed on the surface of the first portion. Further, the first portion contains tungsten, and a nitrogen-containing plasma is generated by supplying a nitrogen-containing gas into the processing chamber and setting an internal pressure of the processing chamber in a range from 133 Pa to 1333 Pa. The surface of the first portion is selectively nitrided without nitriding the surface of the second portion by the nitrogen-containing plasma such that a tungsten nitride film is formed on the surface of the first portion.

### CROSS-REFERENCE TO RELATED APPLICATIONS

This application claims priority to Japanese Patent Application No. 2011-080077 filed on Mar. 31, 2011, the entire contents of which are incorporated herein by reference.

### FIELD OF THE INVENTION

The present invention relates to a plasma nitriding method for forming a nitride film on a surface of a structure, a plasma nitriding apparatus and a method of manufacturing a semiconductor device.

### BACKGROUND OF THE INVENTION

In a process of manufacturing a semiconductor device such as DRAM, a gate insulating layer is formed on a silicon substrate, and a gate electrode is formed on the gate insulating layer. Further, an insulating layer is formed to surround the gate electrode and the gate insulating layer to cover the gate electrode. As an electrode portion of the gate electrode, a laminated body containing, e.g., polysilicon and tungsten is used. The gate insulating layer has a predetermined threshold voltage. Electrons move between the silicon substrate and the gate electrode through the gate insulating layer. Specifically, the movement of the electrons is carried out by applying a voltage, which is equal to or greater than the threshold voltage of the gate insulating layer, between the silicon substrate and the gate electrode. The gate insulating layer is formed of, e.g., silicon oxynitride (SiON). The insulating layer formed to cover the gate electrode is formed of, e.g., silicon oxide (SiO₂). This insulating layer is formed by employing, e.g., chemical vapor deposition (CVD).

Further, the formation of the gate electrode is performed by, e.g., forming a laminated film including the laminated body described above and the gate insulating layer on the silicon substrate, and etching the laminated film. In this case, for example, in order to repair damages or defects in the gate insulating layer caused by etching, an oxidation process may be performed by a thermal oxidation method or the like after forming the gate electrode. Further, after forming the insulating layer to surround the gate electrode, an annealing process may be carried out on the whole layer for various purposes.

When the above oxidation process is performed, since the surface of the gate electrode is exposed to an oxidizing atmosphere, the surface of tungsten forming the gate electrode is oxidized. Further, when the insulating layer made of silicon oxide is formed to surround the gate electrode by CVD, the surface of tungsten is oxidized by an oxygen gas used in CVD. Further, in case where the annealing process is carried out after forming the insulating layer, the oxidation of tungsten is processed by oxygen contained in the silicon oxide. If tungsten is oxidized in this way, tungsten oxide (WOx) is formed and scattered from the surface of tungsten, and voids are formed at the interface between the tungsten oxide and the insulating layer, thereby resulting in a change in voltage characteristics of the gate electrode. Accordingly, it may be impossible to obtain desired electrical characteristics.

Thus, it has been proposed that an anti-oxidation film is formed on the surface of tungsten before the above oxidation process is performed. Also, it has been proposed that, e.g., a nitride film, particularly, tungsten nitride film is used as the anti-oxidation film.

Japanese Patent Application Publication No. 2004-200550 (corresponding to U.S. Patent Application Publication No. 2004/0121526) describes performing a plasma process using a nitrogen-containing gas, and then nitriding sidewalls of a gate electrode formed by a polycrystalline silicon film, a tungsten nitride film and a tungsten film, thereby forming a nitride film. Further, Japanese Patent Application Publication No. H1-189138 describes that an entire tungsten film or its surface layer formed on a silicon substrate is processed and nitrided in a nitrogen-containing gas environment. Also, Japanese Patent Application Publication No. 2000-332259 (corresponding to U.S. Pat. No. 6,614,083) describes that a surface of a tungsten film being used as a wiring material of a thin film transistor (JUT) is covered with tungsten nitride by nitriding such as thermal nitriding or plasma nitriding. Besides, Japanese Patent Application Publication No. H5-243178 (corresponding to U.S. Pat. No. 5,318,924) describes that a local interconnection of a semiconductor integrated circuit, which is formed of a titanium/tungsten layer, is nitrided by rapid thermal annealing (PTA). Moreover, Japanese Patent Application Publication No. 2000-235963 (corresponding to U.S. Patent Application Publication No. 2002/01.23215) describes that a tungsten nitride thin film is formed as a barrier film of copper wiring.

In the technologies disclosed in Patent Documents 1 to 5, the silicon substrate and the entire surface of the structure including the gate electrode are exposed to a nitriding atmosphere when the nitride film is formed. Accordingly, the nitride film is formed on not only the surface of tungsten forming a part of the electrode portion of the gate electrode, but also the surface of a portion containing silicon of the silicon substrate, the gate insulating layer, and polysilicon forming the other part of the electrode portion of the gate electrode. In general, defects are easily formed in the nitride film. Since the nitride film is continuously formed along the surfaces of the silicon substrate and the electrode portion (polysilicon and tungsten), if defects are formed in the nitride film, a leakage may develop between the silicon substrate and tungsten through the defects in the nitride film. Further, if the gate insulating layer is formed of silicon oxynitride, the silicon oxynitride layer may be also nitrided, and the concentration of nitrogen in the silicon oxynitride may change, thereby changing a threshold voltage of the gate insulating layer. Furthermore, it may require a process for removing the nitride film, particularly, silicon nitride (SiN) film, formed on the silicon substrate.

### SUMMARY OF THE INVENTION

In view of the above, the present invention provides a plasma nitriding method for forming a nitride film to cover only a surface of a first portion of a target object having a structure including the first portion containing a metal and a second portion containing silicon, a plasma nitriding apparatus and a method of manufacturing a semiconductor device.

In accordance with a first aspect of the present invention, there is provided a plasma nitriding method including: placing, in a processing chamber, a target object having a structure including a first portion containing a metal and a second portion containing silicon to expose surfaces of the first and the second portion; and performing a plasma process on the target object to selectively nitride the surface of the first portion such that a metal nitride film is selectively formed on the surface of the first portion. Further, the first portion contains tungsten. A nitrogen-containing plasma is generated by supplying a nitrogen-containing gas into the processing chamber and setting an internal pressure of the processing chamber in a range from 133 Pa to 1333 Pa, and the surface of the first portion is selectively nitrided without nitriding the surface of the second portion by the nitrogen-containing plasma such that a tungsten nitride film is formed on the surface of the first portion.

In accordance with a second aspect of the present invention, there is provided a plasma nitriding apparatus which performs a plasma process on a target object having a structure including a first portion containing a metal and a second portion containing silicon to expose surfaces of the first and the second portion, and selectively nitrides the surface of the first portion by the plasma process such that a metal nitride film is selectively formed on the surface of the first portion. The first portion contains tungsten, and the apparatus includes a processing chamber in which the target object is loaded and a specific process is performed; a gas supply unit which supplies a nitrogen-containing gas as a processing gas into the processing chamber; an exhaust unit which vacuum evacuates the processing chamber; a plasma generating unit which generates a plasma in the processing chamber; and a control unit which controls such that the nitrogen-containing gas is supplied into the processing chamber by the gas supply unit, an internal pressure of the processing chamber is set in a range from 133 Pa to 1333 Pa by the exhaust unit, a nitrogen-containing plasma is generated in the processing chamber by the plasma generating unit, and the surface of the first portion is selectively nitrided without nitriding the surface of the second portion by the nitrogen-containing plasma such that a tungsten nitride film is formed on the surface of the first portion.

In accordance with a third aspect of the present invention, there is provided a method of manufacturing a semiconductor device having a structure including a first portion containing a metal and a second portion containing silicon. The first portion contains tungsten, and the method includes: forming an initial laminated film, to become at least a part of the first and the second portion, on a semiconductor substrate; etching the initial laminated film to form the structure such that surfaces of the first and the second portions are exposed; transferring the semiconductor substrate having the structure into a processing chamber; supplying a nitrogen-containing gas into the processing chamber; setting an internal pressure of the processing chamber in a range from 133 Pa to 1333 Pa; generating a nitrogen-containing plasma in the processing chamber; and plasma nitriding to selectively nitride the surface of the first portion without nitriding the surface of the second portion by the nitrogen-containing plasma such that a tungsten nitride film is formed on the surface of the first portion.

### BRIEF DESCRIPTION OF THE DRAWINGS

The objects and features of the present invention will become apparent from the following description of embodiments, given in conjunction with the accompanying drawings, in which:

FIG. 1 is a flowchart illustrating a plasma nitriding method in accordance with an embodiment of the present invention;

FIG. 2 is a cross-sectional view showing a structure before a tungsten nitride film is formed by applying the plasma nitriding method in accordance with the embodiment of the present invention;

FIG. 3 is a cross-sectional view showing a structure after the tungsten nitride film is formed by applying the plasma nitriding method in accordance with the embodiment of the present invention;

FIG. 4 is a cross-sectional view schematically showing a configuration of a plasma nitriding apparatus in accordance with the embodiment of the present invention;

FIG. 5 is a plan view showing a planar antenna in the plasma nitriding apparatus shown in FIG. 4;

FIG. 6 is a diagram illustrating a control unit in the plasma nitriding apparatus shown in FIG. 4.

FIG. 7 is a flowchart illustrating a method of manufacturing a semiconductor device in accordance with the embodiment of the present invention;

FIG. 8 is a characteristic diagram showing a relationship between a pressure in a processing chamber and a nitrogen dose;

FIG. 9 is a characteristic diagram showing a relationship between a pressure in a processing chamber and a nitrogen dose ratio;

FIG. 10 is a cross-sectional view showing a structure in a first comparative example; and

FIG. 11 is a cross-sectional view showing a structure in a second comparative example.

### DETAILED DESCRIPTION OF THE EMBODIMENTS

Hereinafter, an embodiment of the present invention will be described with reference to the accompanying drawings which form a part hereof.

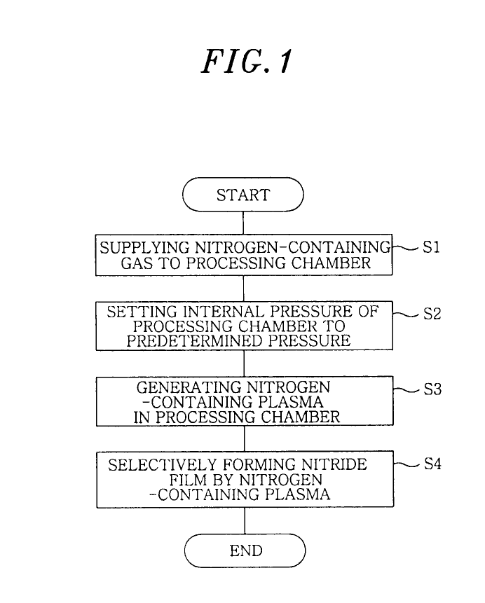

First, a plasma nitriding method in accordance with the embodiment of the present invention will be described with reference to FIG. 1. FIG. 1 is a flowchart showing the plasma nitriding method in accordance with the embodiment of the present invention.

In the plasma nitriding method of this embodiment, placed in a processing chamber is a target object having a structure 100 including a first portion 100A containing a metal and a second portion 100B containing silicon, wherein a surface 100Aa (hereinafter, referred to as a first surface portion) of the first portion 100A and a surface 100Ba (hereinafter, referred to as a second surface portion) of the second portion 100B are exposed, and a plasma process is performed on the target object to selectively nitride only the first surface portion 100Aa, thereby selectively forming a metal nitride film on the first surface portion 100Aa.

The first portion 100A may include, as a layer containing a metal, e.g., a layer made of the metal such as tungsten, or a layer made of a metal nitride such as tungsten nitride. The second portion 100B may include, as a layer containing silicon, e.g., a layer made of silicon, a layer made of silicon oxide (SiO₂), or a layer made of silicon oxynitride (SiON).

As shown in FIG. 1, the plasma nitriding method of this embodiment includes a first to fourth steps S1 to S4. In the first step S1, a nitrogen-containing gas is supplied to the processing chamber in which the target object is loaded. As for the nitrogen-containing gas, e.g., a nitrogen gas (N₂), ammonia gas (NH₃), NO, N₂O or the like may be used

In the second step S2, an internal pressure of the processing chamber is set to be maintained at a predetermined pressure. The internal pressure of the processing chamber is preferably in a range from 133 Pa to 1333 Pa, and more preferably, in a range from 267 Pa to 1333 Pa. The reason for this will be explained in detail later.

In the third step S3, a nitrogen-containing plasma is generated in the processing chamber. Specifically, a microwave is radiated into the processing chamber to form an electromagnetic field, thereby forming a plasma of the nitrogen-containing gas. Further, the nitrogen-containing plasma is preferably a microwave-excited plasma formed by converting the nitrogen-containing gas supplied to the processing chamber into a plasma by the microwave introduced into the processing chamber from a planar antenna having a plurality of slots.

In the fourth step S4, the second surface portion 100Ba is not nitrided and the first surface portion 100Aa is selectively nitrided by the nitrogen-containing plasma, thereby forming a nitride film (metal nitride film) only on the first surface portion 100Aa. In a case where the first portion 100A contains tungsten, a tungsten nitride film is formed on the first surface portion 100Aa. In the fourth step S4, the nitride film is hardly formed on the second surface portion 100Ba. As described above, the nitride film (tungsten nitride film) is selectively formed on the first surface portion 100Aa through the first to fourth steps S1 to S4.

In the above, a case where the nitride film is hardly formed includes a case where the nitride film is never formed and a case where the nitride film is slightly formed, but has almost no impact.

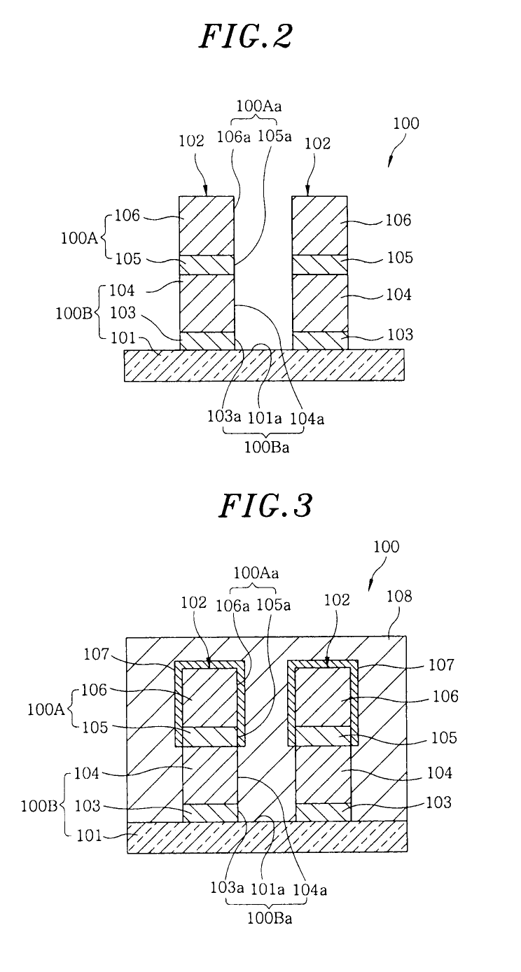

Next, the plasma nitriding method in accordance with the embodiment of the present invention will be described in detail with reference to FIGS. 2 and 3. FIG. 2 is a cross-sectional view showing the structure 100 before the tungsten nitride film is formed through the plasma nitriding method in accordance with the embodiment of the present invention. FIG. 3 is a cross-sectional view showing the structure 100 after the tungsten nitride film is formed through the plasma nitriding method in accordance with the embodiment of the present invention.

In an example of FIG. 2, the structure 100 includes a silicon substrate 101 made of silicon, and two laminated bodies 102 disposed on a portion of an upper surface of the silicon substrate 101. The structure 100 is, e.g., a part of a semiconductor wafer (hereinafter, simply referred to as “wafer”) for manufacturing a semiconductor device. In this example, the laminated bodies 102 include a gate insulating layer 103 made of silicon oxynitride (SiON), a first electrode layer 104 stacked on the gate insulating layer 103 and made of polysilicon, a barrier layer 105 stacked on the first electrode layer 104 and made of tungsten nitride, and a second electrode layer 106 stacked on the barrier layer 105 and made of tungsten. The laminated bodies 102 correspond to a gate electrode of, e.g., DRAM. An electrode portion of the gate electrode includes the first electrode layer 104, the barrier layer 105 and the second electrode layer 106. The laminated bodies 102 are formed by etching a laminated film using, e.g., lithography, dry etching or the like.

Further, the structure 100 includes the first portion 100A containing a metal and the second portion 100B containing silicon. In this embodiment, the first portion 100A contains tungsten as the metal. In the example shown in FIG. 2, the first portion 100A includes the barrier layer 105 and the second electrode layer 106. Further, the second portion 100B includes the gate insulating layer 103 and the first electrode layer 104.

Further, in the example shown in FIG. 2, the first surface portion 100Aa which is the surface of the first portion 100A includes a surface 105a of the barrier layer 105 and a surface 106a of the second electrode layer 106 containing tungsten. Further, the second surface portion 100Ba which is the surface of the second portion 100B includes a surface 101a of the silicon substrate 101, a surface 103a of the gate insulating layer 103 and a surface 104a of the first electrode layer 104 containing silicon.

As described above, the plasma nitriding method in accordance with the embodiment of the present invention includes selectively nitriding the first surface portion 100Aa, thereby forming a metal nitride film on the first surface portion 100Aa. In a case where the first portion 100A contains tungsten, a tungsten nitride film is formed on the first surface portion 100Aa. In this embodiment, the wafer W having the structure 100 is arranged in the processing chamber and a plasma nitriding process is performed on the wafer W through the first to fourth steps S1 to S4. In the fourth step S4, the plasma nitriding process is performed by the nitrogen-containing plasma, so that a nitride film is hardly formed on the second surface portion 100Ba having the surfaces of silicon-containing layers, and a tungsten nitride film 107 is selectively formed on the first surface portion 100Aa having the surfaces tungsten-containing layers. The tungsten nitride film 107 is formed by nitriding tungsten of the surface of the first portion 100A (the barrier layer 105 and the second electrode layer 106). Further, experimental results showing that the nitride film is hardly formed on the second surface portion 100Ba will be described in detail later.

FIG. 3 illustrates an example in which the laminated bodies 102 including the gate insulating layer 103, the first electrode layer 104, the barrier layer 105 and the second electrode layer 106 are formed on the silicon substrate 101, the tungsten nitride film 107 is selectively formed on the first surface portion 100Aa which is the surface of the first portion 100A (the barrier layer 105 and the second electrode layer 106), and an insulating layer 108 made of silicon oxide (SiO₂) is formed around the laminated bodies 102 to cover the laminated bodies 102 by employing, e.g., chemical vapor deposition (CVD).

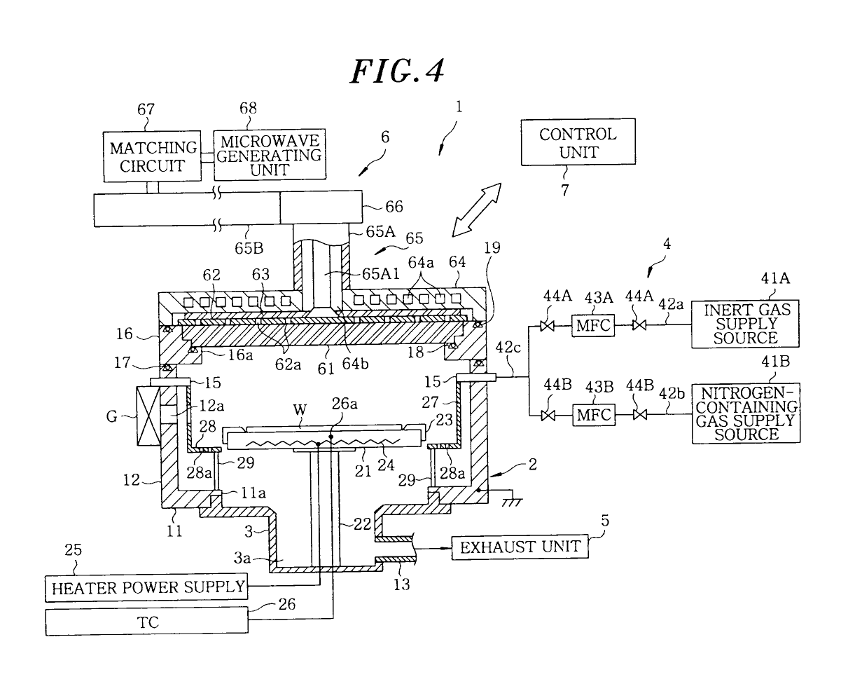

Next, a plasma nitriding apparatus in accordance with the embodiment the present invention will be described with reference to FIG. 4. FIG. 4 is a cross-sectional view schematically showing a configuration of the plasma nitriding apparatus in accordance with the embodiment of the present invention. A plasma nitriding apparatus 1 of this embodiment includes a planar antenna having a plurality of slot-shaped holes, particularly, a radial line slot antenna (RLSA). A plasma processing apparatus including the RLSA is also called an RLSA microwave plasma processing apparatus. In the RLSA microwave plasma processing apparatus, a microwave is directly introduced into the processing chamber by the RLSA to thereby generate a microwave-excited plasma with high density and low electron temperature.

The plasma nitriding apparatus 1 includes a processing chamber 2 accommodating the wafer W serving as a target object, a mounting table 21 placed in the processing chamber 2 to mount the wafer W thereon, an exhaust chamber 3 connected to the processing chamber 2, and a gas supply unit 4 for supplying a gas into the processing chamber 2. The plasma nitriding apparatus 1 further includes an exhaust unit 5 for vacuum evacuating an inner space of the processing chamber 2, a microwave introducing unit 6 for introducing a microwave into the processing chamber 2 to generate a plasma, and a control unit 7 for controlling each component of the plasma nitriding apparatus 1. Further, as a unit for supplying a gas into the processing chamber 2, an external gas supply unit which is not included in the plasma nitriding apparatus 1 may be used instead of the gas supply unit 4.

The processing chamber 2 has a tubular shape open at the top and is formed in, e.g., a substantially cylindrical shape or substantially polygonal tubular shape. The processing chamber 2 is formed of, e.g., a metal material such as aluminum. Further, the processing chamber 2 is grounded. The microwave introducing unit 6 is provided at the top of the processing chamber 2 and functions as a plasma generating unit for introducing an electromagnetic wave (microwave) into the processing chamber 2 to generate a plasma. A configuration of the microwave introducing unit 6 will be described in detail later.

The processing chamber 2 has a plate-shaped bottom portion 11 and a sidewall portion 12 connected to the bottom portion 11. The sidewall portion 12 has a loading/unloading port 12a through which the wafer W is loaded/unloaded between the processing chamber 2 and a transfer chamber (not shown) adjacent to the processing chamber 2. A gate valve G is provided between the processing chamber 2 and the transfer chamber. The gate valve G serves to open and close the loading/unloading port 12a. The gate valve G is configured such that the processing chamber 2 is hermetically sealed in its closed state and the wafer W is transferred between the processing chamber 2 and the transfer chamber in its open state.

The bottom portion 11 has an opening 11a formed in its central portion. The exhaust chamber 3 has an inner space 3a communicating with the opening 11a, and is connected to the bottom portion 11 such that the exhaust chamber 3 protrudes downward from the bottom portion 11.

The plasma nitriding apparatus 1 further includes an exhaust pipe 13 for communicating with the inner space 3a. The exhaust pipe 13 is connected to the exhaust unit 5. The exhaust unit 5 is connected to the exhaust chamber 3 through the exhaust pipe 13. The exhaust unit 5 has a high speed vacuum pump capable of quickly reducing an internal pressure of the processing chamber 2 and the exhaust chamber 3 to a predetermined vacuum level. A turbo molecular pump or the like may be used as the high speed vacuum pump, for example. By operating the high speed vacuum pump of the exhaust unit 5, the internal pressure of the processing chamber 2 and the exhaust chamber 3 may be reduced to a predetermined vacuum level. That is, the gas supplied to the processing chamber 2 from the gas supply unit 4 uniformly flows into the inner space 3a of the exhaust chamber 3. The gas is exhausted through the exhaust pipe 13 by operating the exhaust unit 5. Accordingly, the internal pressure of the processing chamber 2 and the exhaust chamber 3 is reduced to a predetermined vacuum level.

The plasma nitriding apparatus 1 further includes a support member 22 for supporting the mounting table 21 in the processing chamber 2 and the exhaust chamber 3. The mounting table 21 is configured to mount the wafer W serving as a target object to be held horizontally. The mounting table 21 is formed of, e.g., ceramic such as AlN and Al₂O₃. Further, the mounting table 21 is preferably formed of a material, e.g., AlN, with high thermal conductivity. The support member 22 has a cylindrical shape extending from the bottom of the exhaust chamber 3 toward an inner space of the processing chamber 2. The support member 22 is formed of, e.g., ceramic such as AlN.

The plasma nitriding apparatus 1 further includes a protective member 23 to protect the mounting table 21. The protective member 23 has an annular shape and serves to protect an upper surface (wafer mounting surface) of the mounting table 21 and one side or both sides of a side surface of the mounting table 21 and also to guide the wafer W. The protective member 23 blocks contact between the mounting table 21 and the plasma to prevent the mounting table 21 from sputtering, thereby preventing impurities from contaminating the wafer W. The protective member 23 is formed of, e.g., quartz, single crystalline silicon, polysilicon, amorphous silicon, SiN or the like. In particular, the protective member 23 made of quartz is preferable because it has the excellent characteristics of the protective member. Further, the protective member 23 is preferably formed of a high purity material with low content of impurities such as alkali metal or other metal.

The plasma nitriding apparatus 1 further includes a heater 24, a heater power supply 25, and a thermocouple 26 (denoted by TC in FIG. 4). The heater 24 and a temperature measuring portion 26a of the thermocouple 26 are embedded in the mounting table 21. The heater 24 is connected to the heater power supply 25 installed outside the processing chamber 2 and the exhaust chamber 3 via, e.g., a wire passing through the inside of the support member 22. The heater power supply 25 supplies an electrical output to the heater 24, thereby heating the mounting table 21. The heater 24 uniformly heats the wafer W serving as a target object by heating the mounting table 21. Temperature of the mounting table 21 is measured by the thermocouple 26. Accordingly, the temperature of the wafer W may be controlled, e.g., in a range from room temperature to 900° C.

Although not shown, the mounting table 21 has support pins provided to protrude from and retreat into the upper surface (wafer mounting surface) of the mounting table 21. The support pins are moved up and down by a lifting mechanism and configured such that the wafer W can be delivered between the processing chamber 2 and the transfer chamber (not shown) at a raised position of the support pins.

The plasma nitriding apparatus 1 further includes a liner 27 and a baffle plate 28 provided on the outside of the periphery of the mounting table 21 in the inner space of the processing chamber 2, and support columns 29 for supporting the baffle plate 28. The liner 27 has a cylindrical shape opened at the top and bottom. The baffle plate 28 is provided to uniformly evacuate the processing chamber 2. The baffle plate 28 is formed in an annular shape and has exhaust holes 28a. Further, the baffle plate 28 is connected to a lower end portion of the liner 27. The liner 27 and the baffle plate 28 are formed of, e.g., quartz.

The plasma nitriding apparatus 1 further includes a gas inlet 15 provided at the sidewall portion 12 of the processing chamber 2. The gas inlet 15 is connected to the gas supply unit 4 for supplying a nitrogen-containing gas or plasma excitation gas. Further, in an example shown in FIG. 4, the gas inlet 15 has an annular shape. However, the gas inlet 15 may be configured in a shape of a nozzle or shower head.

The gas supply unit 4 includes gas supply sources (e.g., an inert gas supply source 41A and a nitrogen-containing gas supply source 41B), lines (e.g., gas lines 42a, 42b and 42c), flow rate controllers (e.g., mass flow controllers (MFCs) 43A and 43B), and valves (e.g., opening and closing valves 44A and 44B). Further, the gas supply unit 4 may further have a purge gas supply source or the like used when changing the atmosphere in the processing chamber 2.

The inert gas supply source 41A and the nitrogen-containing gas supply source 41B are connected to the gas inlet 15 through the gas lines 42a, 42b and 42c. That is, the inert gas supply source 41A is connected to one end of the gas line 42a. The nitrogen-containing gas supply source 41B is connected to one end of the gas line 42b. Both of the other ends of the gas lines 42a and 42b are connected to one end of the gas line 42c. The other end of the gas line 42c is connected to the gas inlet 15. The MFC 43A is located between the inert gas supply source 41A and the gas inlet 15. The MFC 43B is located between the nitrogen-containing gas supply source 41B and the gas inlet 15. The opening and closing valves 44A are located at the upstream and downstream sides of the MFC 43A. The opening and closing valves 44B are located at the upstream and downstream sides of the MFC 43B.

A rare gas such as Ar gas, Kr gas, Xe gas and He gas is used as an inert gas supplied into the processing chamber 2. Among these gases, particularly, Ar gas is preferably used in terms of cost effectiveness. Further, the nitrogen-containing gas is a gas containing nitrogen atoms, and for example, a nitrogen gas (N₂), ammonia gas (NH₃), NO, N₂O or the like is used as the nitrogen-containing gas being supplied into the processing chamber 2.

The inert gas supplied from the inert gas supply source 41A reaches the gas inlet 15 through the gas lines 42a and 42c, and is introduced into the processing chamber 2 through the gas inlet 15. The nitrogen-containing gas supplied from the nitrogen-containing gas supply source 41B reaches the gas inlet 15 through the gas lines 42b and 42c, and is introduced into the processing chamber 2 through the gas inlet 15. The types, flow rates and the like of gases being supplied into the processing chamber 2 are controlled by the MFCs 43A and 43B and the opening and closing valves 44A and 44B.

The plasma nitriding apparatus 1 further includes an annular plate 16 connected to an upper end portion of the sidewall portion 12, and a seal member 17 hermetically sealing a gap between the processing chamber 2 (sidewall portion 12) and the annular plate 16. The plate 16 has a support portion 16a formed to protrude toward the inner space of the processing chamber 2. The support portion 16a has an annular shape.

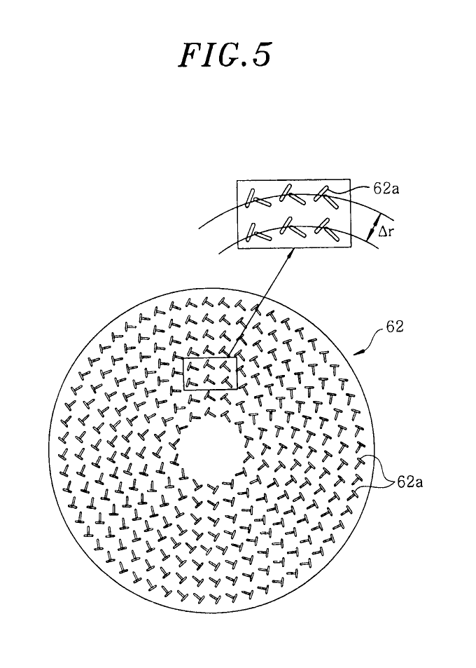

Hereinafter, a configuration of the microwave introducing unit 6 will be described with reference to FIGS. 4 and 5. FIG. 5 is a plan view showing a planar antenna in the plasma nitriding apparatus 1. As described above, the microwave introducing unit 6 is provided at the top of the processing chamber 2 and functions as a plasma generating unit which introduces an electromagnetic wave (microwave) into the processing chamber 2 to generate a plasma. The microwave introducing unit 6 includes a transmitting plate 61 transmitting a microwave, a planar antenna 62 arranged to face the mounting table 21, a slow-wave member 63 shortening a wavelength of the microwave to adjust the plasma, a cover member 64 covering the planar antenna 62 and the slow-wave member 63, a waveguide 65 propagating the microwave to the planar antenna 62, a mode convertor 66 converting a mode of the microwave propagating through the waveguide 65, a microwave generating unit 68 generating the microwave, and a matching circuit 67 provided between the waveguide 65 and the microwave generating unit 68.

The transmitting plate 61 is disposed on the support portion 16a of the plate 16. The transmitting plate 61 is formed of a dielectric material, e.g., quartz, Al₂O₃, AlN or the like. The plasma nitriding apparatus 1 further includes a seal member 18 hermetically sealing a gap between the transmitting plate 61 and the support portion 16a, thereby maintaining airtightness of the processing chamber 2.

The planar antenna 62 is disposed on the transmitting plate 61 (on the side of the transmitting plate 61 opposite to the processing chamber 2) to face the mounting table 21. The planar antenna 62 has a disc shape. Further, the planar antenna 62 may have a rectangular plate shape without being limited to a disc shape. Further, in the example shown in FIG. 4, the planar antenna 62 has a planar shape larger than the transmitting plate 61 (when seen from above). In this example, the periphery of the planar antenna 62 is suspended and fixed on an upper end of the plate 16. The planar antenna 62 is formed of a conductive material, e.g., a gold or silver plated copper plate, aluminum plate, nickel plate or an alloy thereof.

As shown in FIG. 5, the planar antenna 62 has microwave radiation holes 62a to radiate the microwave therethrough. The microwave radiation holes 62a are formed in a specific shape to pass through the planar antenna 62. In an example shown in FIG. 5, each of the radiation holes 62a has an elongated rectangular shape (slot shape). Further, each pair of the microwave radiation holes 62a, i.e., two adjacent microwave radiation holes, are generally arranged in a shape. The pairs of the microwave radiation holes 62a combined and arranged in a specific shape (e.g., T shape) are arranged in a concentric circular pattern.

The length and arrangement interval of the microwave radiation holes 62a are determined according to the wavelength (λg) of the microwave. Specifically, for example, the microwave radiation holes 62a are arranged such that the arrangement interval ranges from λg/4 to λg. Further, in FIG. 5, when the pairs of the microwave radiation holes 62a are arranged in a concentric circular pattern, the arrangement interval in a radial direction is represented by Δr.

Further, the microwave radiation holes 62a may have other shapes such as circular shape and circular arc shape without being limited to the slot shape. Moreover, the microwave radiation holes 62a may be arranged in other patterns, e.g., spiral or radial pattern without being limited to the concentric circular pattern.

The slow-wave member 63 is disposed on an upper surface of the planar antenna 62. Further, the slow-wave member 63 is formed of a material having a larger dielectric constant than that of the vacuum. For example, quartz, polytetrafluoroethylene resin, polyimide resin or the like may be used as the material of the slow-wave member 63. The microwave has a longer wavelength in the vacuum. The slow-wave member 63 functions to shorten the wavelength of the microwave to adjust the plasma.

Further, the planar antenna 62 may not be in contact with the transmitting plate 61, but it is preferable that the planar antenna 62 is in contact with the transmitting plate 61. Further, the slow-wave member 63 may not be in contact with the planar antenna 62, but it is preferable that the slow-wave member 63 is in contact with the planar antenna 62.

The cover member 64 is connected to the upper end of the plate 16 to cover the planar antenna 62 and the slow-wave member 63. The plasma nitriding apparatus 1 further includes a seal member 19 hermetically sealing a gap between the cover member 64 and the plate 16. The cover member 64 is formed of a metal material such as aluminum and stainless steel. Although not shown, the cover member 64 is grounded. Further, the cover member 64 has a cooling water passage 64a formed therein, and an opening 64b formed in a central portion of the ceiling of the cover member 64. The transmitting plate 61, the planar antenna 62, the slow-wave member 63 and the cover member 64 are cooled by flowing cooling water in the cooling water passage 64a.

A space enclosed by the cover member 64 and the planar antenna 62 forms a flat waveguide. The slow-wave member 63 is disposed in the flat waveguide. The microwave is uniformly supplied into the processing chamber 2 through the flat waveguide.

The waveguide 65 includes a coaxial waveguide 65A having a circular cross sectional shape perpendicular to its extending direction, and a rectangular waveguide 65B having a rectangular cross sectional shape perpendicular to its extending direction. The coaxial waveguide 65A extends in a vertical direction in FIG. 4. The rectangular waveguide 65B extends in a lateral direction (horizontal direction) in FIG. 4. One end of the coaxial waveguide 65A is connected to an upper end of the opening 64b of the cover member 64. The other end of the coaxial waveguide 65A is connected to one end of the rectangular waveguide 65B via the mode convertor 66. The mode convertor 66 functions to convert the microwave propagating in a TE mode in the rectangular waveguide 65B into a TEM mode microwave.

The coaxial waveguide 65A has an internal conductor 65A1 extending to an inner space of the coaxial waveguide 65A. A lower end of the internal conductor 65A1 is connected to a central portion of the planar antenna 62. Accordingly, the microwave is efficiently, uniformly and radially propagated to the flat waveguide formed with the cover member 64 and the planar antenna 62 through the internal conductor 65A1.

The microwave generating unit 68 is connected to the other end of the rectangular waveguide 65B via the matching circuit 67. The microwave generated at a predetermined frequency (e.g., 2.45 GHz) in the microwave generating unit 68 is propagated to the planar antenna 62 through the waveguide 65, and introduced into the processing chamber 2 from the microwave radiation holes 62a through the transmitting plate 61. Further, the frequency of the microwave may be 8.35 GHz, 1.98 GHz or the like without being limited to 2.45 GHz.

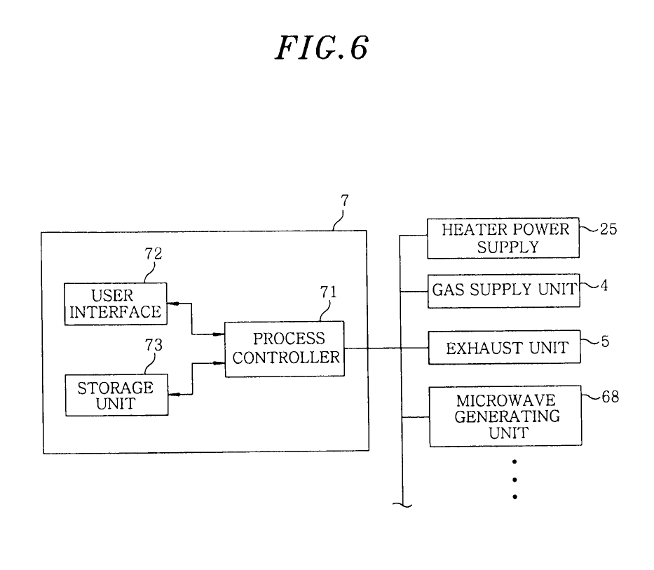

Next, the control unit 7 will be described with reference to FIG. 6. FIG. 6 is a diagram illustrating the control unit 7 in the plasma nitriding apparatus 1 shown in FIG. 4. Each component of the plasma nitriding apparatus 1 is connected to and controlled by the control unit 7. The control unit 7 is generally a computer. In an example shown in FIG. 6, the control unit 7 includes a process controller 71 having a CPU, and a user interface 72 and a storage unit 73, which are connected to the process controller 71.

The process controller 71 is a controller for generally controlling respective components (e.g., the heater power supply 25, the gas supply unit 4, the exhaust unit 5, the microwave generating unit 68 and the like) associated with the process conditions such as temperature, pressure, gas flow rate, microwave output and the like in the plasma nitriding apparatus 1. The user interface 72 includes a keyboard or touch panel for allowing a process operator to perform an input operation of commands in order to manage the plasma nitriding apparatus 1, a display for visually displaying an operational status of the plasma nitriding apparatus 1, or the like.

The storage unit 73 stores a recipe including process condition data or control programs (software) for performing various processes in the plasma nitriding apparatus 1 under the control of the process controller 71. If necessary, a certain control program or recipe is retrieved from the storage unit 73 in accordance with instructions inputted through the user interface 72 and executed by the process controller 71. Accordingly, a desired process is performed in the processing chamber 2 of the plasma nitriding apparatus 1 under the control of the process controller 71.

The control program and recipe may be used from those stored in a computer-readable storage medium (e.g., CD-ROM, hard disk, flexible disk, flash memory, DVD, blu-ray disc and the like). Further, the recipe may be transmitted at any time from other devices via, e.g., a dedicated line to be available online.

In this embodiment, the control unit 7 controls each component of the plasma nitriding apparatus 1 to perform the plasma nitriding method in accordance with the embodiment of the present invention. Specifically, the control unit 7 controls to perform the plasma nitriding method in accordance with the embodiment of the present invention, the method including supplying the nitrogen-containing gas into the processing chamber 2 from the gas supply unit 4, setting the internal pressure of the processing chamber 2 in a range from 133 Pa to 1333 Pa (preferably, from 267 Pa to 1333 Pa) by using the exhaust unit 5, generating the nitrogen-containing plasma in the processing chamber 2 by employing the microwave introducing unit 6, and selectively nitriding the first surface portion 100Aa serving as the surface of the first portion 100A without nitriding the second surface portion 100Ba serving as the surface of the second portion 100B shown in FIG. 2 by using the nitrogen-containing plasma, thereby forming the nitride film (tungsten nitride film) on the first surface portion 100Aa.

As described above, the plasma nitriding apparatus 1 includes, as main elements, the processing chamber 2, the mounting table 21, the exhaust chamber 3, the gas supply unit 4, the exhaust unit 5, the microwave introducing unit 6, and the control unit 7. In the plasma nitriding apparatus 1 configured above, a plasma process causing less damage to a base film, substrate (wafer W) or the like may be performed at a low temperature equal to or lower than 600° C. (e.g., in a range from room temperature (about 25° C.) to 600° C.). Further, the plasma nitriding apparatus 1 may achieve process uniformity even on a large-diameter wafer W (target object) since it has excellent plasma uniformity.

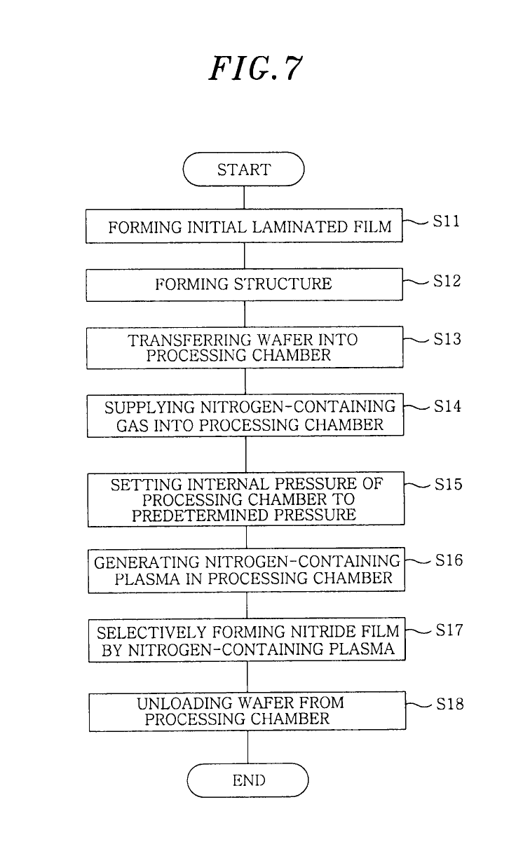

Next, procedures of the plasma nitriding process using the RLSA type plasma nitriding apparatus 1 will be described while explaining a method of manufacturing a semiconductor device in accordance with the embodiment of the present invention with reference to FIG. 7. FIG. 7 is a flowchart illustrating the method of manufacturing a semiconductor device in accordance with the embodiment of the present invention.

The method of manufacturing a semiconductor device of this embodiment is to manufacture a semiconductor device having a structure including a first portion containing a metal and a second portion containing silicon. A case of manufacturing a semiconductor device having the structure 100 shown in FIG. 2 will be described as an example. The structure 100 includes the first portion 100A containing tungsten as the metal, and the second portion 100B containing silicon. Further, the structure 100 has the silicon substrate 101 and two laminated bodies 102. The laminated bodies 102 have the gate insulating layer 103, the first electrode layer 104, the barrier layer 105 and the second electrode layer 106. The first portion 100A includes the barrier layer 105 and the second electrode layer 106. The second portion 100B includes the silicon substrate 101, the gate insulating layer 103 and the first electrode layer 104.

As shown in FIG. 7, the method of manufacturing a semiconductor device in accordance with this embodiment includes forming an initial laminated film (step S11), forming a structure (step S12), transferring a wafer into a processing chamber (step S13), supplying a nitrogen-containing gas into the processing chamber (step S14), setting an internal pressure of the processing chamber to a predetermined pressure (step S15), generating a nitrogen-containing plasma in the processing chamber (step S16), selectively forming a nitride film by applying the nitrogen-containing plasma (plasma nitriding step S17), and unloading the wafer from the processing chamber (step S18).

In the step S11 of forming an initial laminated film, an initial laminated film that will become at least a part of the first and the second portion 100A and 100B is formed on the wafer W (silicon substrate 101). In case of the example shown in FIG. 2, the initial laminated film includes a layer made of silicon oxynitride (SiON) that will become the gate insulating layer 103, a layer made of polysilicon that will become the first electrode layer 104, a layer made of tungsten nitride that will become the barrier layer 105, and a layer made of tungsten that will become the second electrode layer 106.

In the step S12 of forming the structure 100, the initial laminated film is etched and the structure 100 is formed to expose the first surface portion 100Aa which is the surface of the first portion 100A and the second surface portion 100Ba which is the surface of the second portion 100B. The structure 100 is formed by etching the initial laminated film by using, e.g., photolithography, dry etching or the like.

In the step S13 of transferring the wafer W into the processing chamber 2, the wafer W on which the structure 100 is formed is transferred into the processing chamber 2. Specifically, first, the gate valve G (see FIG. 4) is set in an open state. Then, the wafer W on which the structure 100 is formed is loaded into the processing chamber 2 at the loading/unloading port 12a and mounted on the upper surface (wafer mounting surface) of the mounting table 21 by a transfer device (not shown). Then, the gate valve G is set in a closed state.

The step S14 of supplying a nitrogen-containing gas into the processing chamber corresponds to the first step S1 shown in FIG. 1. The step S15 of setting an internal pressure of the processing chamber to a predetermined pressure corresponds to the second step S2 shown in FIG. 1. The step S16 of generating a nitrogen-containing plasma in the processing chamber corresponds to the third step S3 shown in FIG. 1. The step S17 of selectively forming a nitride film by applying the nitrogen-containing plasma corresponds to the fourth step S4 shown in FIG. 1. These steps will be described below.

In the step S14 of supplying a nitrogen-containing gas into the processing chamber, while the processing chamber 2 is vacuum evacuated by the exhaust unit 5, an inert gas and a nitrogen-containing gas are respectively introduced into the processing chamber 2 at predetermined flow rates from the inert gas supply source 41A and the nitrogen-containing gas supply source 41B through the gas inlet 15. In the step S15 of setting an internal pressure of the processing chamber to a predetermined pressure, while introducing the inert gas and the nitrogen-containing gas, the internal pressure of the processing chamber 2 is controlled to be maintained at a predetermined pressure by the exhaust unit 5. In the same way as in the second step S2 shown in FIG. 1, the internal pressure of the processing chamber 2 is preferably in a range from 133 Pa to 1333 Pa, and more preferably, in a range from 267 Pa to 1333 Pa.

In the step S16 of generating a nitrogen-containing plasma in the processing chamber, a nitrogen-containing plasma is generated in the processing chamber 2 as follows. In this step, the microwave of a predetermined frequency (e.g., 2.45 GHz) generated in the microwave generating unit is transmitted to the waveguide 65 via the matching circuit 67. The microwave transmitted to the waveguide 65 sequentially passes through the rectangular waveguide 65B, the mode convertor 66 and the coaxial waveguide 65A, and is supplied to the planar antenna 62 through the internal conductor 65A1. The microwave propagates in a TE mode in the rectangular waveguide 65B, and the TE mode microwave is converted into a TEM mode microwave by the mode convertor 66. The TEM mode microwave propagates in the coaxial waveguide 65A toward the planar antenna 62. Then, the microwave is radiated to the space above the wafer W in the processing chamber 2, through the transmitting plate 61, from the microwave radiation holes 62a formed in a slot shape to pass through the planar antenna 62.

As described above, an electromagnetic field is formed in the processing chamber 2 by the microwave radiated into the processing chamber 2, and processing gases such as the inert gas and the nitrogen-containing gas are converted into a plasma, thereby generating a nitrogen-containing plasma.

In the step S17 of selectively forming a nitride film by the nitrogen-containing plasma, the first surface portion 100Aa is selectively nitrided by the nitrogen-containing plasma without nitriding the second surface portion 100Ba, thereby forming a nitride film only on the first surface portion 100Aa. In the example shown in FIG. 2, since the first portion 100A contains tungsten, a tungsten nitride film is formed on the first surface portion 100Aa. In this step, the nitride film is hardly formed on the second surface portion 100Ba.

Further, the plasma nitriding process (plasma nitriding step) of this embodiment is hardly affected by the conditions other than the plasma process conditions described above. Accordingly, in addition to the above, e.g., the types and flow rate ratio of processing gases, microwave power, processing temperature and the like are also important as the plasma process conditions, but general conditions can be employed for those conditions.

An example of other plasma process conditions will be described. As a processing gas, Ar gas is used as the rare gas, and N₂ gas is used as the nitrogen-containing gas. A flow rate ratio (volume ratio) of the N₂ gas to the whole processing gas ranges, e.g., from 10% to 70%. The microwave power density ranges, e.g., from 0.255 W/cm² to 2.55 W/cm². Further, the microwave power density means the microwave power per 1 cm² area of the transmitting plate 61. The temperature of the mounting table 21 is set to be in a range, e.g., from room temperature (about 25° C.) to 600° C. The processing time depends on other plasma process conditions, but ranges, e.g., from 10 seconds to 180 seconds. By radiating the microwave through the microwave radiation holes 62a of the planar antenna 62, the microwave-excited plasma has a high density of approximately ranging from 1×10¹⁰ to 5×10¹²/cm³, and also has a low electron temperature of approximately 1.2 eV or less in the vicinity of the wafer W.

The above process conditions may be stored as a recipe in the storage unit 73 of the control unit V. Further, the process controller 71 reads out the recipe and transmits a control signal to each component (e.g., the gas supply unit 4, the exhaust unit 5, the microwave generating unit 68, the heater power supply 25 and the like) of the plasma nitriding apparatus 1, thereby achieving the plasma nitriding process under the desired conditions.

In the step S18 of unloading the wafer from the processing chamber, after the first surface portion 100Aa is selectively nitrided to form the nitride film, the wafer W is unloaded from the processing chamber 2. Specifically, first, the gate valve G is set in an open state. Then, the wafer W mounted on the upper surface (wafer mounting surface) of the mounting table 21 is unloaded from the processing chamber 2 through the loading/unloading port 12a by the transfer device (not shown). Then, the gate valve G is set in a closed state.

Moreover, the method of manufacturing a semiconductor device in accordance with this embodiment may further include forming the insulating layer 108 (see FIG. 3) to cover the structure 100 after the step S18 of unloading the wafer from the processing chamber. In this step, first, the wafer W, on which the nitride film (e.g., tungsten nitride film) has been formed as described above, is loaded into a processing chamber of another apparatus (e.g., CVD apparatus) performing a process of forming the insulating layer 108. Then, the insulating layer 108 made of silicon oxide is formed to cover the structure 100 by employing, e.g., CVD.

Besides, the method of manufacturing a semiconductor device in accordance with this embodiment may further include performing an annealing process on the entire structure 100 after forming the insulating layer 108. Moreover, the method of manufacturing a semiconductor device in accordance with this embodiment may further include performing an oxidation process by a thermal oxidation method or the like in order to repair damages or defects in, e.g., the gate insulating layer 103 before forming the insulating layer 108 after the plasma nitriding step S17.

As described above, in the plasma nitriding method, the plasma nitriding apparatus, and the semiconductor device manufacturing method in accordance with this embodiment, the nitrogen-containing gas is supplied into the processing chamber 2, and the internal pressure of the processing chamber 2 is set in a range from 133 Pa to 1333 Pa, so that the nitrogen-containing plasma is generated in the processing chamber 2. Then, the first surface portion 100Aa is selectively nitrided by the nitrogen-containing plasma without nitriding the second surface portion 100Ba, thereby forming the tungsten nitride film on the first surface portion 100Aa. In this embodiment, as apparent from experimental results that will be described later, the nitride film is hardly formed on the second surface portion 100Ba which is the surface of the second portion 100B containing silicon. Accordingly, in accordance with this embodiment, it is possible to form the nitride film (e.g., tungsten nitride film 107) covering only the first surface portion 100Aa which is the surface of the first portion 100A.

Further, in accordance with this embodiment, as described above, since the nitride film is hardly formed on the second surface portion 100Ba, it is possible to prevent a leakage from developing between the silicon substrate 101 and the first and the second electrode layer 104 and 106 of the laminated bodies 102. Further, in accordance with this embodiment, it is possible to prevent variation in threshold voltage of the gate insulating layer 103 due to nitrogen concentration changes in the silicon oxynitride forming the gate insulating layer 103 of the laminated bodies 102.

Further, in this embodiment, the tungsten nitride film 107 functions as an anti-oxidation film of the first portion 100A. Accordingly, in accordance with this embodiment, even when the insulating layer 108 made of silicon oxide is formed to cover the structure 100 by employing, e.g., CVD after forming the tungsten nitride film 107, it is possible to prevent the first portion 100A from being oxidized. Similarly, in accordance with this embodiment, it is possible to prevent the first portion 100A from being oxidized even when an annealing process is performed on the entire structure 100 after forming the insulating layer 108, or when an oxidation process is performed by a thermal oxidation method or the like in order to repair damages or defects in, e.g., the gate insulating layer 103 between the plasma nitriding step and the step of forming the insulating layer 108.

Next, the experimental results showing that the nitride film is hardly formed on the second surface portion 100Ba which is the surface of the second portion 100B containing silicon will be described in detail. First, contents of this experiment will be described. In this experiment, following first to third samples were used. The first sample was a silicon substrate made of silicon. Further, a chemical oxide film was formed on the surface of the silicon substrate. The second sample was prepared by performing thermal oxidation on the surface of the silicon substrate at a high temperature to form a silicon oxide film. In the second sample, the thickness of the silicon oxide film was 6 nm. The third sample was prepared by forming a tungsten film on the surface of the silicon substrate. In the third sample, the thickness of the tungsten film was 50 nm.

The first sample was used to examine whether the nitride film was formed on the silicon substrate, which corresponds to the silicon substrate 101 in this embodiment. The second sample was used to examine whether the nitride film was formed on the silicon oxide film, which corresponds to the gate insulating layer 103 in this embodiment although it was not silicon oxynitride. The third sample was used to examine whether the nitride film was formed on the tungsten film, which corresponds to the second electrode layer 106 in this embodiment.

In the experiment, the plasma nitriding processes were respectively performed on the first to third samples by the plasma nitriding apparatus 1. The plasma process conditions in the experiment were as follows. As a processing gas, Ar gas was used as the rare gas, and N₂ gas was used as the nitrogen-containing gas. The flow rate of the Ar gas was set at 1000 mL/min(sccm) and the flow rate of the N₂ gas was set at 200 mL/min(sccm). The microwave power density was set at 0.77 W/cm². The temperature of the mounting table 21 was set at 500° C. The processing time was set to be 90 seconds. In the experiment, the internal pressure of the processing chamber 2 was varied in a range from 6.6 to 1000 Pa.

Further, in the experiment, as an indicator of whether the nitride film was formed, a nitrogen dose indicating the amount of nitrogen injected per unit area was used. In the measurement of the nitrogen dose, X-ray photoelectron spectroscopy (XPS) was used.

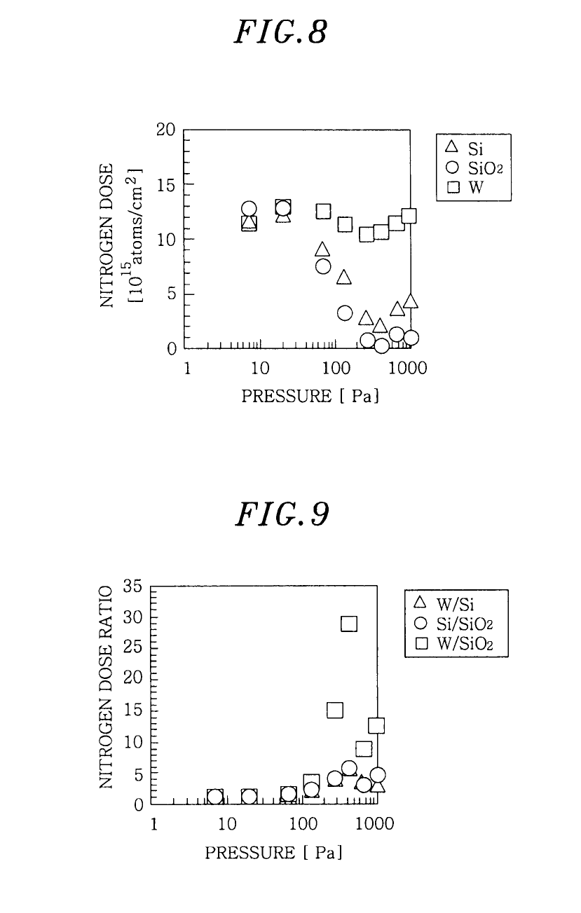

Next, the experimental results will be described with reference to FIGS. 8 and 9. FIG. 8 is a characteristic diagram showing relationships between the pressure in the processing chamber 2 and the nitrogen dose. FIG. 9 is a characteristic diagram showing relationships between the pressure in the processing chamber 2 and a nitrogen dose ratio. Further, the nitrogen dose ratio is a ratio of nitrogen doses of two samples. In FIG. 8, a horizontal axis represents the pressure in the processing chamber 2, and a vertical axis represents the nitrogen dose. Further, in FIG. 8, ‘Δ’, ‘◯’, and ‘□’ respectively represent the nitrogen doses of the first sample (silicon substrate), the second sample (silicon oxide film), and the third sample (tungsten film). In FIG. 9, a horizontal axis represents the pressure in the processing chamber 2, and a vertical axis represents the nitrogen dose ratio. Further, in FIG. 9, ‘Δ’, ‘◯’ and ‘□’ respectively represent a ratio of the nitrogen dose of the third sample to that of the first sample, a ratio of the nitrogen dose of the first sample to that of the second sample, and a ratio of the nitrogen dose of the third sample to that of the second sample.

It can be seen from FIG. 8 that the nitrogen dose decreases as the pressure increases in the first and second samples (silicon substrate and silicon oxide film), whereas the nitrogen dose almost does not change even though the pressure increases in the third sample. In particular, when the pressure becomes equal to or higher than 133 Pa, the nitrogen doses of the first and second samples are significantly reduced. The results of this experiment show that when the pressure becomes equal to or higher than 133 Pa, the nitride film is hardly formed on the first and second samples compared to the third sample. That is, the results of this experiment show that, in this embodiment, when the pressure in the processing chamber 2 becomes equal to or higher than 133 Pa, the nitride film is hardly formed on the second surface portion 100Ba which is the surface of the second portion 100B containing silicon, while the tungsten nitride film 107 is selectively formed on the first surface portion 100Aa which is the surface of the first portion 100A containing tungsten.

Further, although an upper limit of the pressure in the processing chamber 2 was set at 1000 Pa in the experiment, as can be seen from FIG. 8, even at the pressure of 1000 Pa or more, there seems to be the trend that the nitride film is hardly formed on the first and second samples and the nitride film is selectively formed on the third sample. However, it is preferable that the pressure in the processing chamber 2 is equal to or lower than a general upper limit of the pressure, i.e., 1333 Pa, in the plasma nitriding apparatus 1.

Further, as shown in FIG. 9, if the pressure becomes equal to or higher than 267 Pa, both of a ratio of the nitrogen dose of the Third sample (tungsten film) to that of the first sample (silicon substrate) and a ratio of the nitrogen dose of the third sample to that of the second sample (silicon oxide film) become 2.5 or greater and sufficiently large. Accordingly, it is more preferable that the pressure in the processing chamber 2 ranges from 267 Pa to 1333 Pa.

Further, as shown in FIG. 8, if the pressure becomes equal to or higher than 267 Pa, the nitrogen dose of the second sample (silicon oxide film) becomes almost zero, and smaller than that of the first sample (silicon substrate). Thus, in accordance with this embodiment, by continuously performing the plasma nitriding process while setting the pressure in the processing chamber 2 at 267 Pa or more, the nitride film may be also formed to cover the surfaces of the first portion 100A and the silicon substrate 101 while preventing the nitride film from being formed on any layer of silicon oxide or silicon oxynitride.

Next, the effects of this embodiment will be described in detail in comparison with a first and a second comparative example. First, the first comparative example will be described with reference to FIG. 10. FIG. 10 is a cross-sectional view showing a structure 100′ in the first comparative example. In the first comparative example, the insulating layer 108 made of silicon oxide is formed to cover the structure 100′ by CVD without performing the plasma nitriding process in accordance with this embodiment. In FIG. 10, reference numeral 109 denotes a tungsten oxide film formed by oxidizing the second electrode layer 106 made of tungsten when forming the insulating layer 108. When the tungsten oxide film is formed in this way, it may be concerned that it will be impossible to obtain desired electrical characteristics of the gate electrode. Further, although not shown, the tungsten oxide formed in this way is scattered from the surface of the second electrode layer 106, and voids are formed at the interface between the tungsten oxide and the insulating layer 108, thereby resulting in a change in voltage characteristics of the gate electrode. Accordingly, it may be impossible to obtain desired electrical characteristics.

In contrast, in the present embodiment, as described above, since the tungsten nitride film 107 functioning as an anti-oxidation film is formed on the first surface portion 100Aa which is the surface of the first portion 100A of the structure 100 including the second electrode layer 106, it is possible to prevent a change in characteristics of the gate electrode due to oxidation of the second electrode layer 106.

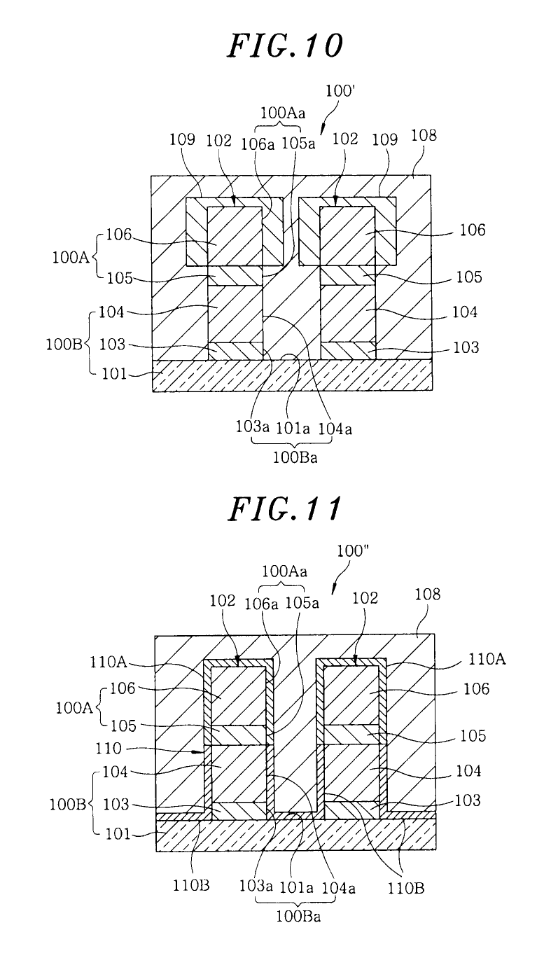

Next, the second comparative example will be described with reference to FIG. 11. FIG. 11 is a cross-sectional view showing a structure 100″ in the second comparative example. In the second comparative example, the plasma nitriding process is performed under the conditions that the nitride film is formed on both of the first surface portion 100Aa and the second surface portion 100Ba (e.g., the pressure is the processing chamber 2 is 133 Pa or less). In this case, the nitride film is also formed on the second surface portion 100Ba which is the surface of the second portion 100B containing silicon. In FIG. 11, reference numeral 110 denotes a nitride film. The nitride film 110 includes a portion 110A formed on the first surface portion 100Aa and a portion 110B formed on the second surface portion 100Ba. The portion 110A is formed of tungsten nitride, and the portion 110B is formed of silicon nitride.

In the second comparative example, since the nitride film 110 is continuously formed along the surfaces of the silicon substrate 101 and the laminated bodies 102, a leakage may develop between the silicon substrate 101 and the first and the second electrode layer 104 and 106 of the laminated bodies 102. Further, since the nitride film 110 (portion 110B) is also formed on the surface 103a of the gate insulating layer 103 of the laminated bodies 102, the concentration of nitrogen in silicon oxynitride included in the gate insulating layer 103 may change, thereby changing the threshold voltage of the gate insulating layer 103. Further, it may require a process for removing the portion 110B of the nitride film 110 formed on the surface 101a of the silicon substrate 101.

In contrast, in the present embodiment, as described above, since the nitride film is hardly formed on the second surface portion 100Ba, the above problem does not occur.

Further, the present invention is not limited to the above-described embodiment, and various modifications may be made. For example, although the RLSA type plasma nitriding apparatus 1 is used in the above embodiment, other types of plasma processing apparatuses may be used. For example, an electron cyclotron resonance (ECR) plasma processing apparatus, a magnetron plasma processing apparatus, a surface wave plasma (SWP) processing apparatus or the like may be used.

Further, although a gate electrode for use in DRAM has been described as the laminated bodies 102 of the structure 100 in the embodiment, the laminated bodies 102 may have other structures having a similar structure containing tungsten in a semiconductor device.

While the invention has been shown and described with respect to the embodiments, it will be understood by those skilled in the art that various changes and modification may be made without departing from the scope of the invention as defined in the following claims.

What is claimed is:

1. A plasma nitriding method comprising:
placing, in a processing chamber, a target object having a structure including a first portion containing a metal and a second portion containing silicon to expose surfaces of the first and the second portion; and
performing a plasma process on the target object to selectively nitride the surface of the first portion such that a metal nitride film is selectively formed on the surface of the first portion,
wherein the first portion contains tungsten, and
wherein a nitrogen-containing plasma is generated by supplying a nitrogen-containing gas into the processing chamber and setting an internal pressure of the processing chamber in a range from 133 Pa to 1333 Pa, and the surface of the first portion is selectively nitrided without nitriding the surface of the second portion by the nitrogen-containing plasma such that a tungsten nitride film is formed on the surface of the first portion.

2. The plasma nitriding method of claim 1, wherein the internal pressure of the processing chamber is set in a range from 267 Pa to 1333 Pa.

3. The plasma nitriding method of claim 1, wherein the second portion includes a silicon substrate made of silicon, and
the first portion is disposed on a portion of an upper surface of the silicon substrate.

4. The plasma nitriding method of claim 2, wherein the second portion includes a silicon substrate made of silicon, and
the first portion is disposed on a portion of an upper surface of the silicon substrate.

5. The plasma nitriding method of claim 1, wherein the structure includes a silicon substrate made of silicon and a laminating body disposed on a portion of an upper surface of the silicon substrate,
wherein the laminating body includes an insulating layer made of silicon oxynitride, a first electrode layer stacked on the insulating layer and made of polysilicon, a barrier layer stacked on the first electrode layer and made of tungsten nitride, and a second electrode layer stacked on the barrier layer and made of tungsten,
wherein the first portion includes the barrier layer and the second electrode layer, and
wherein the second portion includes the silicon substrate, the insulating layer, and the first electrode layer.

6. The plasma nitriding method of claim 2, wherein the structure includes a silicon substrate made of silicon and a laminating body disposed on a portion of an upper surface of the silicon substrate,
wherein the laminating body includes an insulating layer made of silicon oxynitride, a first electrode layer stacked on the insulating layer and made of polysilicon, a barrier layer stacked on the first electrode layer and made of tungsten nitride, and a second electrode layer stacked on the barrier layer and made of tungsten,
wherein the first portion includes the barrier layer and the second electrode layer, and
wherein the second portion includes the silicon substrate, the insulating layer, and the first electrode layer.

7. The plasma nitriding method of claim 1, wherein the nitrogen-containing plasma is a microwave-excited plasma formed by converting the nitrogen-containing gas supplied to the processing chamber into a plasma by a microwave introduced into the processing chamber through a planar antenna having a plurality of slots.

8. The plasma nitriding method of claim 2, wherein the nitrogen-containing plasma is a microwave-excited plasma formed by converting the nitrogen-containing gas supplied to the processing chamber into a plasma by a microwave introduced into the processing chamber through a planar antenna having a plurality of slots.

9. The plasma nitriding method of claim 4, wherein the nitrogen-containing plasma is a microwave-excited plasma formed by converting the nitrogen-containing gas supplied to the processing chamber into a plasma by a microwave introduced into the processing chamber through a planar antenna having a plurality of slots.

10. The plasma nitriding method of claim 6, wherein the nitrogen-containing plasma is a microwave-excited plasma formed by converting the nitrogen-containing gas supplied to the processing chamber into a plasma by a microwave introduced into the processing chamber through a planar antenna having a plurality of slots.

11. A plasma nitriding apparatus which performs a plasma process on a target object having a structure including a first portion containing a metal and a second portion containing silicon to expose surfaces of the first and the second portion, and selectively nitrides the surface of the first portion by the plasma process such that a metal nitride film is selectively formed on the surface of the first portion, wherein the first portion contains tungsten, the apparatus comprising:
a processing chamber in which the target object is loaded and a specific process is performed;
a gas supply unit which supplies a nitrogen-containing gas as a processing gas into the processing chamber;
an exhaust unit which vacuum evacuates the processing chamber;
a plasma generating unit which generates a plasma in the processing chamber; and
a control unit which controls such that the nitrogen-containing gas is supplied into the processing chamber by the gas supply unit, an internal pressure of the processing chamber is set in a range from 133 Pa to 1333 Pa by the exhaust unit, a nitrogen-containing plasma is generated in the processing chamber by the plasma generating unit, and the surface of the first portion is selectively nitrided without nitriding the surface of the second portion by the nitrogen-containing plasma such that a tungsten nitride film is formed on the surface of the first portion.

12. A method of manufacturing a semiconductor device having a structure including a first portion containing a metal and a second portion containing silicon, wherein the first portion contains tungsten, the method comprising:
forming an initial laminated film, to become at least a part of the first and the second portion, on a semiconductor substrate;
etching the initial laminated film to form the structure such that surfaces of the first and the second portions are exposed;
transferring the semiconductor substrate having the structure into a processing chamber;
supplying a nitrogen-containing gas into the processing chamber;
setting an internal pressure of the processing chamber in a range from 133 Pa to 1333 Pa;
generating a nitrogen-containing plasma in the processing chamber; and
plasma nitriding to selectively nitride the surface of the first portion without nitriding the surface of the second portion by the nitrogen-containing plasma such that a tungsten nitride film is formed on the surface of the first portion.

13. The method of claim 12, further comprising forming an insulating layer made of silicon oxide to cover the structure after the plasma nitriding.
